(19) United States
(12) Patent Application Publication
(10) Pub. No.: US 2025/0324592 A1
(43) Pub. Date: Oct. 16, 2025

(54) MANAGING THREE-DIMENSIONAL SEMICONDUCTOR DEVICES

(71) Applicant: Yangtze Memory Technologies Co., Ltd., Wuhan (CN)

(72) Inventors: Zhaosong LI, Wuhan (CN); Liyuan ZHANG, Wuhan (CN); Shasha LIU, Wuhan (CN); Jianlan WEI, Wuhan (CN); Sizhe LI, Wuhan (CN); Xiaoming MAO, Wuhan (CN); Bao JIN, Wuhan (CN); Jianquan JIA, Wuhan (CN); Jing GAO, Wuhan (CN); Zongliang HUO, Wuhan (CN)

(21) Appl. No.: 18/741,752

(22) Filed: Jun. 12, 2024

(30) Foreign Application Priority Data
Apr. 15, 2024 (CN) 202410454270.3

(51) Int. Cl. H10B 43/27; G11C 16/04; H10B 41/10; H10B 41/27; H10B 41/35; H10B 43/10; H10B 43/35

(52) U.S. Cl. CPC H10B 43/27; G11C 16/0483; H10B 41/10; H10B 41/27; H10B 41/35; H10B 43/10; H10B 43/35

(57) ABSTRACT

Systems, devices, and methods for managing three-dimensional (3D) semiconductor devices are provided. In one aspect, a semiconductor device includes a stack structure with at least one gate line, a select gate layer and at least one channel structure. The at least one gate line includes a first material. The select gate layer includes a second material different from the first material. The at least one channel structure extends through the stack structure and the select gate layer along a first axis. Each channel structure of the at least one channel structure includes a layered structure.

### CROSS-REFERENCE TO RELATED APPLICATIONS

This application claims priority to Chinese Patent Application No. 202410454270.3, filed on Apr. 15, 2024, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for managing select gates in three-dimensional (3D) semiconductor devices.

One aspect of the present disclosure features a semiconductor device, including a stack structure includes at least one gate line, where the at least one gate line includes a first material. A select gate layer includes a second material different from the first material. At least one channel structure extends through the stack structure and the select gate layer along a first axis. Each channel structure of the at least one channel structure includes a layered structure.

In some implementations, the second material includes a doped polysilicon.

In some implementations, the layered structure includes a blocking layer, a charge trapping layer, a dielectric layer, and a semiconductor channel layer. The semiconductor channel layer is in contact with and laterally surrounded by the dielectric layer. The dielectric layer is in contact with and laterally surrounded by the charge trapping layer. The charge trapping layer is in contact with and laterally surrounded by the blocking layer.

In some implementations, the blocking layer comprises silicon oxide. The charge trapping layer comprises silicon nitride. The dielectric layer comprises silicon oxide. The semiconductor channel layer comprises doped polysilicon.

In some implementations, the semiconductor device further includes a select gate cut structure extending through the select gate layer along the first axis. The select gate cut structure is configured to separate the select gate layer into a plurality of isolated portions. The select gate cut structure is in contact with one or more channel structures of the at least one channel structure.

In some implementations, the select gate cut structure has a straight-line shape or a wavy shape in a first plane of the semiconductor device, wherein the first plane is orthogonal to the first axis.

In some implementations, the each channel structure further includes a channel plug. The channel plug and the layered structure is stacked together along the first axis. The channel plug is in contact with the semiconductor channel layer. A width of the channel plug is larger than a width of the semiconductor channel layer.

In some implementations, the width of the channel plug is a dimension along a second axis, wherein the second axis is orthogonal to the first axis.

Another aspect of the present disclosure features a semiconductor device including: a stack structure comprising at least one gate line and a select gate layer. The at least one channel structure extends through at least the stack structure along a first axis. Each channel structure of the at least one channel structure includes a layered structure, the layered structure comprising a blocking layer, a charge trapping layer, a dielectric layer, and a semiconductor channel layer. Each channel structure also includes a channel plug. The channel plug and the layered structure is stacked together along the first axis. The channel plug is in contact with the semiconductor channel layer. The channel plug is at least partially in contact with a channel contact. A select gate cut structure extends through at least the select gate layer along the first axis and configured to separate the select gate layer into a plurality of isolated portions. The select gate cut structure is in contact with one or more channel structures of the at least one channel structure.

In some implementations, a first material of the select gate layer is different from a second material of the at least one gate line.

In some implementations, the first material of the select gate layer comprises doped polysilicon, and the second material of the at least one gate line comprises tungsten.

In some implementations, the at least one channel structure extends through both the stack structure and the select gate layer along the first axis, and wherein the blocking layer comprises silicon oxide, the charge trapping layer comprises silicon nitride, the dielectric layer comprises silicon oxide, and the semiconductor channel layer comprises doped polysilicon.

In some implementations, a width of the channel plug is larger than a width of the semiconductor channel layer.

In some implementations, the select gate cut structure has a straight-line shape or a wavy shape in a first plane of the semiconductor device, wherein the first plane is orthogonal to the first axis.

Another aspect of the present disclosure features a method including: forming a stack structure along a first axis comprising a plurality of insulating layers; forming a select gate layer; forming at least one channel structure extending through the stack structure and the select gate layer along the first axis. Each channel structure of the at least one channel structure includes a layered structure, the layered structure comprising a blocking layer, a charge trapping layer, a dielectric layer, and a semiconductor channel layer. The method further includes forming a select gate cut structure extending through at least the select gate layer. The select gate cut structure is configured to separate the select gate layer into a plurality of isolated portions.

In some implementations, the stack structure further includes a plurality of sacrificial layers interleaved with the plurality of insulating layers. The method further comprises replacing the plurality of sacrificial layers with a plurality of conductive layers.

In some implementations, a first material of the select gate layer is different from a second material of the plurality of conductive layers.

In some implementations, the each channel structure of the at least one channel structure further includes a channel plug. The channel plug and the layered structure is stacked together along the first axis. The channel plug is in contact with the semiconductor channel layer. A width of the channel plug is larger than a width of the semiconductor channel layer.

In some implementations, the select gate cut structure is in contact with one or more channel structures of the at least one channel structure.

In some implementations, the select gate cut structure has a straight-line shape or a wavy shape in a first plane of the semiconductor device, wherein the first plane is orthogonal to the first axis.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example semiconductor device.

FIGS. 2A-2D illustrate cross-sectional views of an example semiconductor device at various stages of a fabrication process.

FIGS. 3A-3H illustrate views of an example semiconductor device with a channel plug at various stages of a fabrication process.

FIGS. 4A-4B illustrate top plane views of an example memory device.

FIG. 5 illustrates a flow chart of an example process to form a semiconductor device.

FIG. 6 illustrates a block diagram of a system having one or more semiconductor devices.

It is to be understood that the various exemplary implementations shown in the figures are merely illustrative representations and are not necessarily drawn to scale.

### DETAILED DESCRIPTION

In some 3D memory devices, such as 3D NAND memory devices, a stack of gate electrodes may be arranged over a substrate, with a plurality of semiconductor channels through and intersecting word lines, into the implanted substrate. The bottom/lower gate electrode or electrodes function as source select gate lines, which are also called bottom select gates (BSG) in some cases. The top/upper gate electrode or electrodes function as drain select gate lines, which are also called top select gates (TSG) in some cases. The gate electrodes between the top/upper select gate electrodes and the bottom/lower gate electrodes function as word lines (WL). The intersection of a word line and a semiconductor channel forms a memory cell.

This disclosure describes a semiconductor device and a method to form such semiconductor device. The semiconductor device includes a stack structure with at least one gate line and a select gate layer. The select gate layer has a material different from that of the gate lines. For example, the gate lines can include Tungsten (W), while the select gate layer includes doped polysilicon. At least one channel structure extends through both the stack structure and the select gate layer along a first axis. Each channel structure has a layered structure, where the layered structure can include a blocking layer, a charge trapping layer, a dielectric layer, and a semiconductor channel layer, which are distributed along a radial direction. The layered structure extends along the first axis. In some implementations, a select gate cut structure extends through the select gate layer along the first axis and separates the select gate layers into multiple isolated portions. The select gate cut structure can be in contact with or partially interferes with at least one channel structure. In some implementations, at least one channel structure includes a channel plug which is stacked together with the layered structure along the first axis. The channel plug is in contact with the semiconductor channel layer and a width of the channel plug is larger than a width of the semiconductor channel layer.

Implementations of the present disclosure can provide one or more of the following technical advantages and/or benefits. Firstly, channel trenches for forming memory strings are formed that extend through both a stack structure, e.g., the interleaved insulating layers and gate lines, and a select gate layer, e.g., top select gate or bottom select gate. An additional trench etch process for the select gate layer is not required, contributing to a reduction in manufacturing costs. Moreover, the formation of channel trenches and select gate cut structures can be before the replacement of sacrificial layers with conductive materials for gate lines. This sequential process mitigates alignment issues between the select gate cut structures and channel trenches arising from thermal stress during the replacement process.

Secondly, the top select gate and/or the bottom select gate can have a floating gate configuration. A layered structure for a floating gate is formed on sidewalls of channels and configured to extend along the axial direction of the channel trenches. Because the channel trenches also extend through the select gate layer, the layered structure is partially surrounded by the select gate layer in lateral directions, thus forming floating gate configuration for select gates. A gate-selective voltage can be applied on the select gates for selecting the respective memory strings in operations. With this floating gate configuration, the top select gate and/or the bottom select gate can have better Vt adjustment and control.

Thirdly, the select gate cut structure is positioned between two adjacent rows of channel structures. The select gate cut structure is contact with or partially cuts off these channel structures. Because the select gate cut structure does not substantially or fully cut off the channel structures, these channel structure, in contact with the select gate cut structures, can still be functional channels in which memory cells are formed. Consequently, the requirement for creating dummy channel rows is cased. Without dummy channels, the density of memory cells is enhanced, and manufacturing costs are reduced.

Furthermore, in some implementations, a channel plug is deployed inside the channel trenches which are stacked together with the layered structure. This channel plug can increase the contact area for contacts or vias, thereby expanding the alignment margin in subsequent process steps. It can also reduce the contact resistance between contact/vias and the channel structures.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

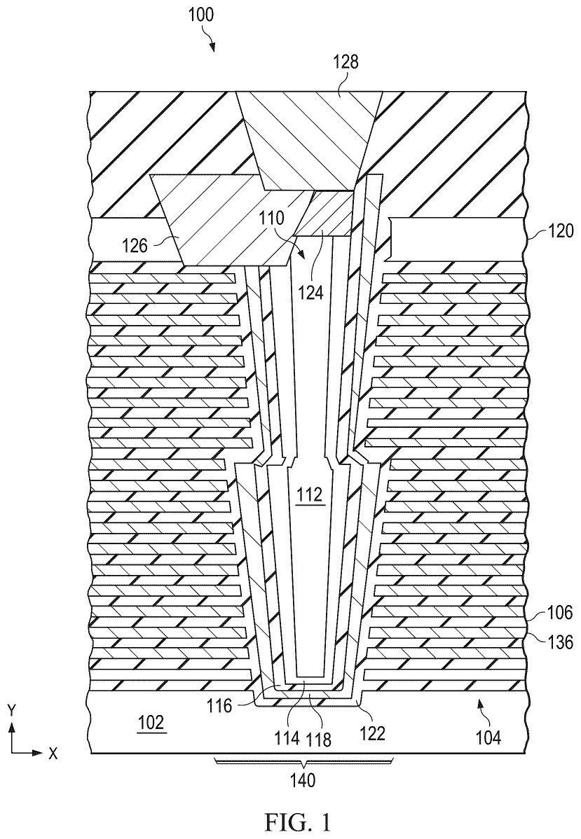

FIG. 1 illustrates a cross-section of an example 3D memory device 100. 3D memory device 100 may include a substrate 102, which is a doped semiconductor layer and may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 102 is a thinned substrate (e.g., a semiconductor layer), which was thinned by grinding, etching, chemical mechanical polishing (CMP), or any combination thereof. Substrate 102 of 3D memory device 100 includes two surfaces (e.g., a top surface and a bottom surface) extending laterally in the x-direction (i.e., the lateral direction). As used herein, whether one component (e.g., a layer or a device) is “on,” “above,” or “below” another component (e.g., a layer or a device) of a 3D memory device (e.g., 3D memory device 100) is determined relative to the substrate of the 3D memory device (e.g., substrate 102) in the y-direction (i.e., the vertical direction) when the substrate is positioned in the lowest plane of the 3D memory device in the y-direction.

In some implementations, 3D memory device 100 is a NAND Flash memory device in which memory cells are provided in the form of an array of NAND memory strings each extending vertically above substrate 102.

As shown in FIG. 1, 3D memory device 100 may include a stack structure 104 with interleaved gate lines 136 and first dielectric layer 106. The gate lines 136 may include conductive materials including, but not limited to, tungsten (W), cobalt (Co), copper (Cu), aluminum (Al), polysilicon, doped silicon, silicides, or any combination thereof. First dielectric layers 106 may include dielectric materials including, but not limited to, silicon oxide, silicon nitride, silicon oxynitride, or any combination thereof.

A select gate (SG) layer 120 can be formed on top of the stack structure 104 which is isolated from the gate lines 136. The select gate layer can comprise a different conductive material than the gate lines. For example, the select gate layer can comprise doped polysilicon while the gate lines can comprise Tungsten (W). The NAND memory string may include one or more channel structures 110 extending vertically through both the stack structure 104 and the select gate layer 120 in the y-direction. In some implementations, there is an additional dielectric layer formed between the select gate layer 120 and the stack structure 104.

Channel structures 110 may include a channel hole or a channel trench with a layered structure 140. In some implementations, the remaining space of channel structure 110 may be partially or fully filled with a filling layer 112 including dielectric materials, such as silicon oxide. In some implementations, the layered structure 140 comprises a blocking layer, a charge trapping layer (also called storage layer in some cases), a dielectric layer (also called a tunneling layer in some cases), and a semiconductor channel layer. The semiconductor channel layer 114 is in contact with and laterally surrounded by the dielectric layer 116. The dielectric layer 116 is in contact with and laterally surrounded by the charge trapping layer 118. The charge trapping layer 118 is in contact with and laterally surrounded by the blocking layer 122. In other words, the filling layer 112, semiconductor channel layer 114, dielectric layer 116, charge trapping layer 118, and blocking layer 122 are arranged radially from the center toward the outer surface of the channel trench in this order. The semiconductor channel layer 114 can include doped polysilicon or silicon germanium (SiGe). The dopants can be N type dopants (e.g., Phosphorus (P) or Arsenic (As)) or P type dopants (e.g., Boron (B) or Gallium (Ga)) at a desired doping level. Dielectric layer 116 may include silicon oxide, silicon oxynitride, or any combination thereof. Charge trapping layer 118 may include silicon nitride, silicon oxynitride, silicon, or any combination thereof. Blocking layer 122 may include silicon oxide, silicon oxynitride, high dielectric constant (high-k) dielectrics, or any combination thereof. In one example, the layered structure 140 can include silicon oxide/silicon oxynitride (or silicon nitride)/silicon oxide/polysilicon (ONOP), for the blocking layer 122, the charge trapping layer 118, the dielectric layer 116, and the semiconductor channel layer 114, respectively.

Channel structure 110 may have a cylinder shape (e.g., a pillar shape). In some implementations, channel structure 110 may be formed by stacking more than one cylinder structure, as shown in FIG. 1. It is understood that the channel structure 110 may have other shapes (e.g., elliptical cylinder or irregular shape).

In some implementations, channel structure 110 may further include a channel contact, or called semiconductor plug, in a lower portion (e.g., at the lower end) of channel structure 110 (not shown). As used herein, the “upper end” of a component (e.g., channel structure 110) is the end farther away from substrate 102 in the positive y-direction, and the “lower end” of the component (e.g., channel structure 110) is the end closer to substrate 102 in the negative y-direction. The channel contact may include a semiconductor material, such as silicon, which is epitaxially grown from substrate 102 in any suitable directions. It is understood that in some implementations, the channel contact includes single crystalline silicon, the same material as substrate 102. In other words, the channel contact may include an epitaxially-grown semiconductor layer that is the same as the material of substrate 102. In some implementations, part of the channel contact is above the top surface of substrate 102 and in contact with semiconductor channel layer 114. The channel contact may function as a channel controlled by a source select gate of the NAND memory string. It is understood that in some implementations, 3D memory device 100 does not include the channel contact, as shown in FIG. 1.

In some implementations, channel structure 110 further includes a channel plug 124 in an upper portion (e.g., at the upper end) of channel structure 110, which can be stacked over the layered structure 140. Channel plug 124 may be in contact with the upper end of semiconductor channel layer 114 of the layered structure 140. In some implementations, the channel plug 124 material can include, but not limited to, TiN, TaN, Al, W, Cu, doped-polysilicon, silicides, or any combination thereof. By covering the upper end of channel structure 110 during the fabrication of 3D memory device 100, channel plug 124 may function as an etch stop layer to prevent etching of dielectrics filled in channel structure 110, such as silicon oxide and silicon nitride. In some implementations, channel plug 124 also functions as the drain of the NAND memory string.

As noted above, the memory array device may include NAND memory strings that extend through interleaved gate lines 136 and first dielectric layers 106, and the stacked conductive/dielectric layer pairs are also referred to as a memory stack. The memory array device may further include select gate layer 120. The channel structure 110 extends through the stack structure 104 and at least partially through the select gate layer 120. As such, a better threshold voltage Vt adjustment or control for the select gate layer 120 can be achieved with the layered structure 140 (e.g., ONOP) in a floating gate configuration.

In some implementations, each gate line 136 in stack structure 104 (e.g., a memory stack) functions as a gate conductor of memory cells in the NAND memory string. Gate lines 136 may extend laterally coupling a plurality of memory cells. In some implementations, memory cell transistors in NAND memory string include semiconductor channel layer 114, memory film (including dielectric layer 116, charge trapping layer 118, and blocking layer 122), and the gate lines 136. The gate lines 136 may further include a gate conductor made from tungsten, adhesion layers including titanium/titanium nitride (Ti/TiN) or tantalum/tantalum nitride (Ta/TaN), and gate dielectric layers made from high-k dielectric materials. As noted above, the select gate layer 120, e.g., drain select layer or source select layer, may comprise different conductive materials than the gate lines 136. For example, the gate lines 136 can comprise Tungsten (W), while the select gate layer 120 can comprise doped polysilicon.

As shown in FIG. 1, select gate layer 120 extends along the x-direction and are divided by an select gate cut structure 126 into two or more portions. Each portion can be a select gate line for corresponding memory strings. A gate-selective voltage may be applied on the select gate line for selecting the respective string in operations.

The select gate cut structure 126 can be in contact with the channel structure 110 and channel plug 124. In other words, the select gate cut structure 126 partially extends into the channel structure 110 and/or the channel plug 124. In some implementations, select gate cut structure 126 is formed by a dielectric material. Select gate cut structure 126 is used for electrically insulating the select gate lines between two adjacent memory strings. By forming the select gate layer 120 around the layered structure 140, a better Vt adjustment for select gate can be achieved with a floating gate structure (e.g., ONOP). In some implementations, although not shown in FIG. 1, it is understood that in a memory array, multiple channel structures 110 are included. As described below, in some implementations, the select gate cut structure 126 is in contact with at least one of the channel structures 110, though not with all of them.

As the select cut structure 126 only partially extends into the channel structure 110, the channel structure 110 can still be functional channels in which memory cells are formed. Consequently, this memory device structure reduces the number of dummy channel structures allowing for an increased density of memory strings.

In some implementations, the memory array device includes a channel contact 128 on top of the select gate cut structure 126 and the channel plug 124. As noted above, the select gate cut structure 126 partially extends into at least one of the channel structures 110. As such, the channel contact 128 can be at least partially in contact with the top end of the channel plug 124. The channel contact 128 may comprise conductive materials including, but not limited to, tungsten (W), cobalt (Co), copper (Cu), aluminum (Al), polysilicon, doped silicon, silicides, or any combination thereof. The channel contact 128 can be configured to connect memory cells to bit lines (not shown), back end of line (BEOL) metal routings (not shown) and/or peripheral circuitry (not shown). It is understood that, in some implementations, the channel plug 124 may not be included in the channel structures 110. In this case, the channel contact 128 lands on the top end of the channel structure 110, including the semiconductor channel layer 114.

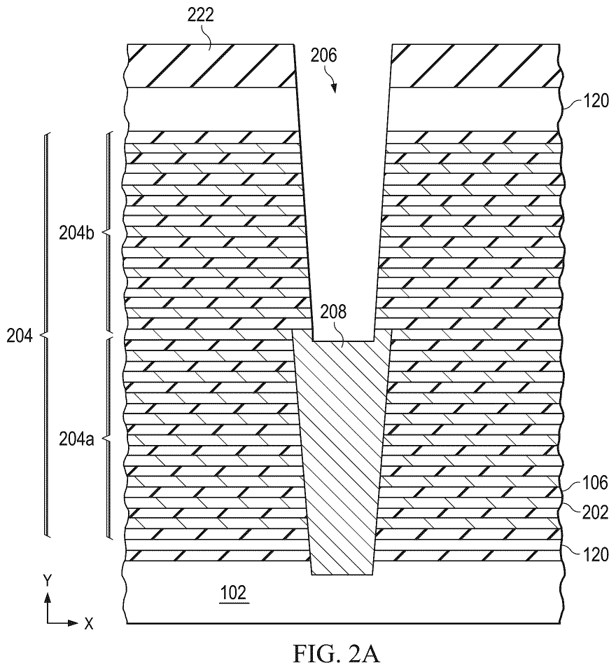

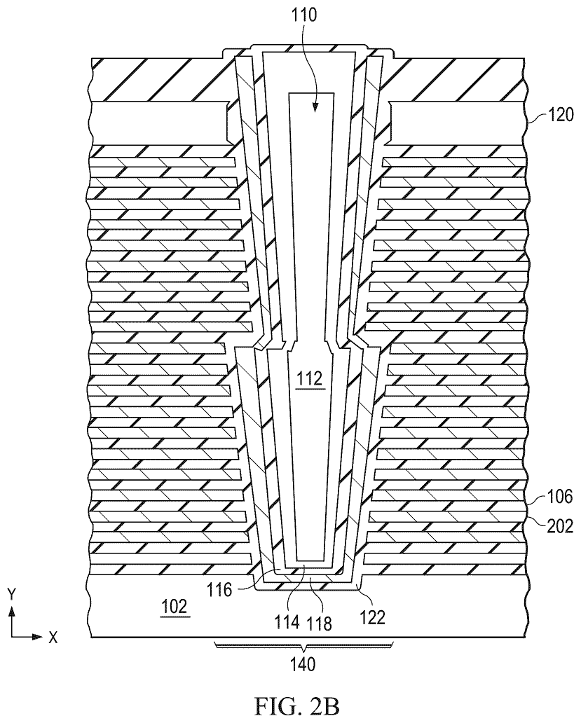

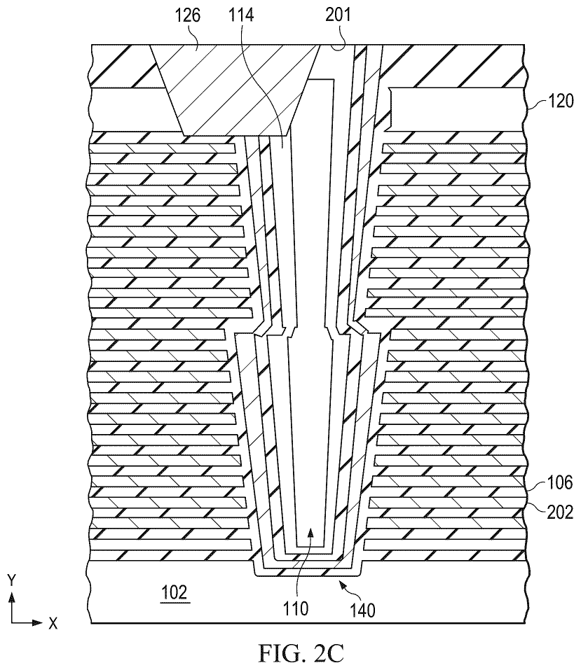

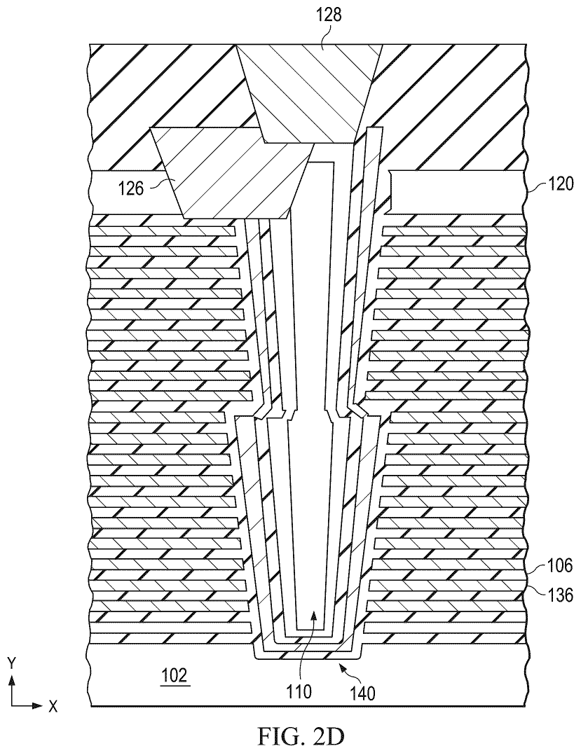

FIGS. 2A-2D illustrate cross-sectional view of an example 3D semiconductor device at various stages of a fabrication process. As illustrated in FIG. 2A, an interleaved structure 204 is formed which includes interleaved sacrificial layer 202 and insulating layer, e.g., first dielectric layer 106. The sacrificial layer 202 can be configured to be replaced with a conductive material to form gate lines 136 at a later stage of the process as described below. First dielectric layers 106 may comprise dielectric materials including, but not limited to, silicon oxide, silicon nitride, silicon oxynitride, or any combination thereof. Sacrificial layers 202 may also include dielectric materials including, but not limited to, silicon oxide, silicon nitride, silicon oxynitride, or any combination thereof. Sacrificial layer 202 can comprise a different material than the first dielectric layer 106 such that it can be selectively removed and replaced with a conductive material at a later processing stage. For example, the sacrificial layer includes silicon nitride, while the first dielectric layer includes silicon oxide.

In some implementations, a select gate layer 120, e.g., for bottom select gate or source select gate, is formed on the substrate 102 prior to the formation of the interleaved structure 204. Another select gate layer 120, e.g., for top select gate or drain select gate, is formed on top of the interleaved structure 204 along positive Y axis, as illustrated in FIG. 2A. The select gate layer 120 may comprise materials including but not limited to doped polysilicon. The first dielectric layers 106 and the sacrificial layers 202 can be deposited using one or more thin film deposition processes, including, but not limited to, chemical vapor deposition (CVD), physical vapor deposition (PVD), atomic layer deposition (ALD), sputtering, or any combination thereof. In some implementations, a second dielectric layer 222 can be formed on top of the select gate layer 120, as illustrated in FIG. 2A.

One or more channel trenches 206 are formed which extend through the select gate layer 120 and the interleaved structure 204 and being in contact with the substrate 102. FIG. 2A illustrates an example channel trench 206. In some implementations, the channel trenches 206 extend partially into the substrate 102. In some implementations, the channel trench has a cylinder shape. Because of etching process, the cylinder may have a larger top opening compared to the bottom opening. In some implementations, the channel trench may be formed by stacking more than one cylinder trench, as shown in FIG. 2A. In such cases, a first portion 204(a) of interleaved structure 204 is deposited on the substrate 102 followed by a trench etch extending through the first portion of interleaved structure 204. The first portion of channel trenches 206 is then filled with a sacrificial filling material 208, which is removed at a later stage as described below. The sacrificial filling material 208 may include dielectric materials including, but not limited to, silicon oxide, silicon nitride, silicon oxynitride, or any combination thereof.

A second portion 204(b) of interleaved structure 204 and the select gate layer 120 is deposited on top of the first portion 204(a) of interleaved structure 204, followed by a trench etch process to form the second portion of channel trenches 206. As illustrated in FIG. 2A, the channel trenches 206 can have a stacked cylinder shape which extends through the second dielectric layer 222, the select gate layer 120, the interleaved structure 204, another select gate layer 120 and into the substrate 102. It is understood that between the interleaved structure 204 and the select gate layer 120, one or more additional dielectric layers can be deposited for isolation purpose. The trench etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

As illustrated in FIG. 2B, the sacrificial filling material 208 is removed by etching. A layered structure 140 is deposited on sidewalls of the channel trenches 206. As noted above, the layered structure 140 comprises a blocking layer 122, a charge trapping layer 118 (also called storage layer in some cases), a dielectric layer 116 (also called a tunneling layer in some cases), and a semiconductor channel layer 114. The semiconductor channel layer 114, the dielectric layer 116, the charge trapping layer 118, and the blocking layer 122 are arranged radially from the center toward the outer surface of the channel trenches 206 in this order. This arrangement can be achieved by depositing theses layers sequentially on sidewalls of the channel trenches 206 in reverse order. Dielectric layer 116 may include silicon oxide, silicon oxynitride, or any combination thereof. Charge trapping layer 118 may include silicon nitride, silicon oxynitride, silicon, or any combination thereof. Blocking layer 122 may include silicon oxide, silicon oxynitride, high dielectric constant (high-k) dielectrics, or any combination thereof. Semiconductor channel layers 114 may include polysilicon. In one example, the layered structure 140 includes silicon oxide/silicon oxynitride (or silicon nitride)/silicon oxide/polysilicon (ONOP). The layered structure 140 can be deposited using one or more thin film deposition processes, including, but not limited to, chemical vapor deposition (CVD), physical vapor deposition (PVD), atomic layer deposition (ALD), sputtering, or any combination thereof. In some implementations, an implantation process is performed to dope the polysilicon for the semiconductor channel layer.

A filling layer 112 is deposited into the vacancies of channel trenches 206. A channel structure 110 is formed which at least includes the layered structure 140 and the filling layer 112. The filling layer 112 can be a dielectric material, including but not limited to, silicon oxide, silicon nitride, silicon oxynitride, or any combination thereof.

In some implementations, a top portion of the filling layer 112 can be recessed with an etching process. The recessed space can be then filled with a conductive material (e.g., a material same as the semiconductor channel material).

The layered structure 140 extends at least partially though the select gate layers 120 and the interleaved structure 204 along Y axis, as illustrated in FIG. 2B. The layered structure 140 can form a floating gate structure for the select gate layers 120, providing benefit of better threshold voltage Vt control for the top select gate and/or the bottom select gate.

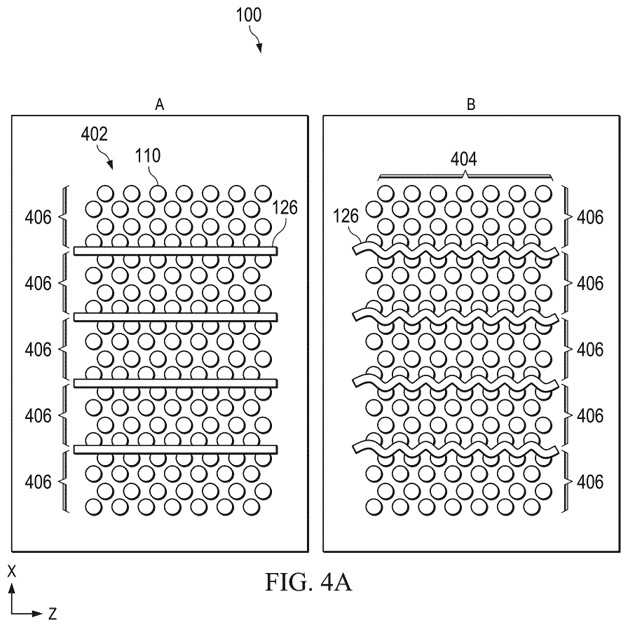

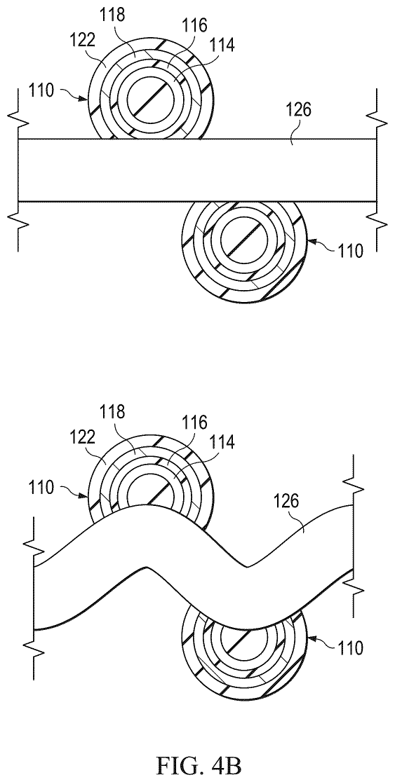

As illustrated in FIG. 2C, a select gate cut structure 126 is formed which extends through the select gate layer 120 along Y axis and partially into the channel structure 110 along X axis. The select gate cut structure 126 divides the select gate layer 120 into multiple isolated portions for electrically insulating select gate lines between two adjacent memory strings. As described below in FIG. 4, the select gate cut structure 126 is formed between two adjacent rows of channel structures 110 and is in contact with or extends into the channel structures 110 in these two adjacent rows. The select gate cut structure 126 may have a straight-line shape or a wavy shape extending along the Z axis on a top plane (e.g., the X-Z plane perpendicular to the Y axis), as shown in FIG. 4. In some implementations, the select gate cut structure 126 can be configured to avoid any contact or interference with the channel structures 110.

Referring back to FIG. 2C, the select gate cut structure 126 can be formed by etching trenches in combination with a lithography process in the select gate layer 120. A part of upper side of the channel structure 110 can be removed during the trench etching process, exposing the semiconductor channel layer 114. The trenches are then filled with suitable materials (e.g., a dielectric material) to form the select gate cut structure 126. Thus, the select gate cut structure 126 can partially extend into the channel structure 110 and be in contact with the semiconductor channel layer 114. At this stage, the top surface 201 of the channel structure 110 is at least partially exposed. In some implementations, the select gate cut structure 126 extends through at least one sacrificial layer 202 or first dielectric layer 106 of the stack structure 104 along Y axis (not shown).

In some implementations, the select gate cut structure 126 comprises a dielectric material. In some implementations, the select gate cut structure 126 comprises an insulating layer, an adhesive layer and a conductive layer. The insulating layer can comprise dielectric material, including but not limited to, silicon oxide, silicon nitride, silicon oxynitride, or any combination thereof. The adhesive layer can comprise material, including but not limited to, TiN, TaN, or any combination thereof. The conductive layer can comprise materials, including but not limited to, TiN, TaN, Al, W, Cu, doped-polysilicon, silicides, or any combination thereof. The insulating layer can be deposited by one or more thin film deposition processes including, but not limited to, CVD, PVD, ALD, MOCVD, MBE, sputtering, or any combination thereof. The conductive layer and the adhesive layer can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof.

As illustrated in FIG. 2D, a channel contact 128 is formed on top of both the select gate cut structure 126 and the channel structure 110. In some implementations, when the channel structures 110 are not interfered with the select gate cut structure 126 (see row 404 of channel structures 110 in FIG. 4A), the channel contact 128 is formed only on top of the channel structure 110. The channel contacts 128 can be isolated from one another with dielectric materials in between. The channel contact 128 can be configured to connect memory cells to bit lines (not shown), back end of line (BEOL) metal routings (not shown) and/or peripheral circuitry (not shown). The channel contact 128 can comprise conductive materials, including but not limited to, TiN, TaN, Al, W, Cu, doped-polysilicon, silicides, or any combination thereof.

The sacrificial layers 202 are replaced with a conductive material to form gate lines 136, as illustrated in FIG. 2D. The gate lines 136 are isolated from one another by the first dielectric layers 106. In some implementations, sacrificial layers 202 may be removed by a wet etch and/or dry etch process. After the removal of sacrificial layers 202, a plurality of openings may be formed between adjacent first dielectric layers 106. Then, a conductive material is deposited into the openings to form gate lines 136. In some implementations, gate lines 136 may include conductive materials including, but not limited to, W, Co, Cu, Al, polysilicon, doped silicon, silicides, or any combination thereof. In some implementations, the gate lines 136 may be formed by one or more thin film deposition processes including, but not limited to, CVD, PVD, ALD, MOCVD, MBE, sputtering, or any combination thereof.

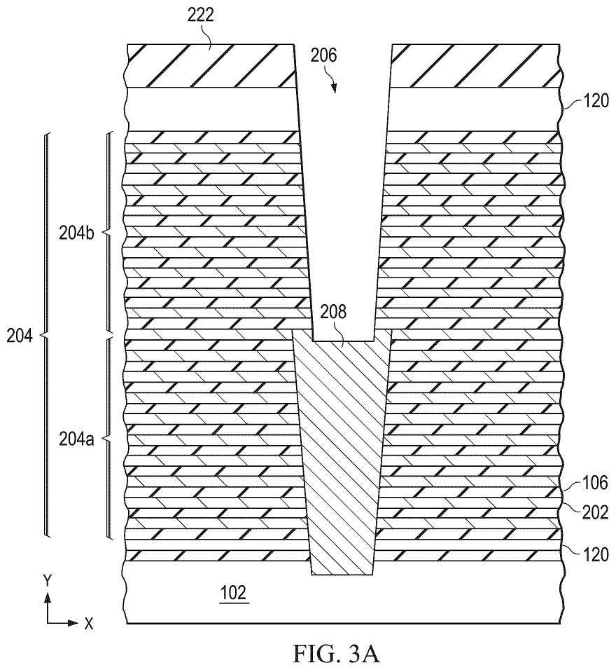

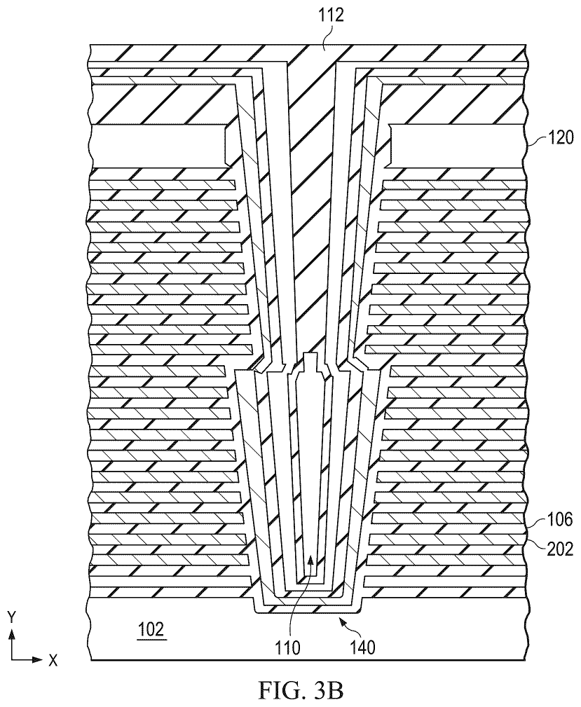

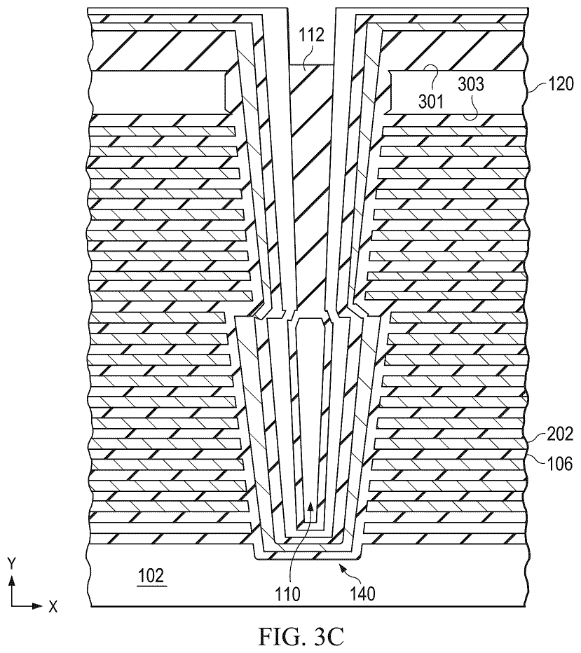

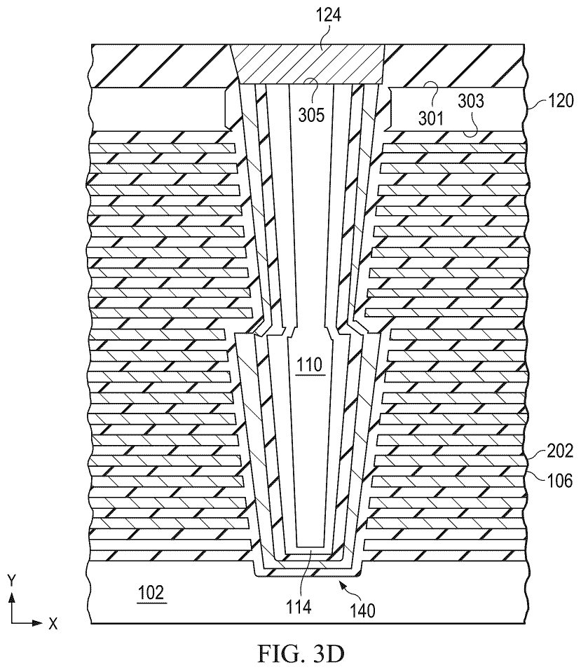

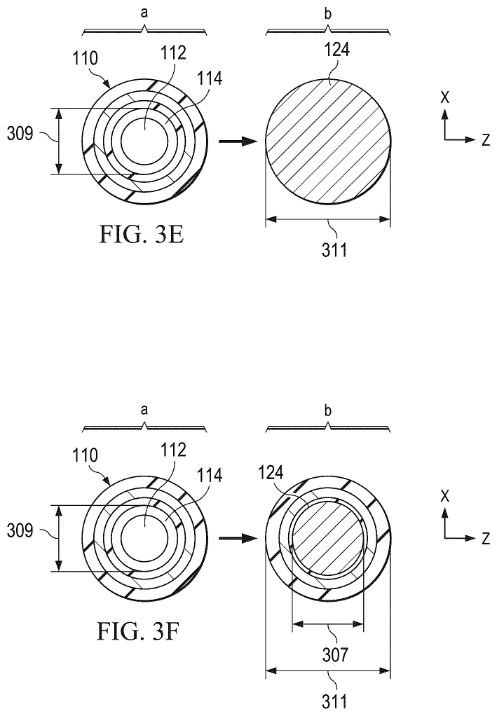

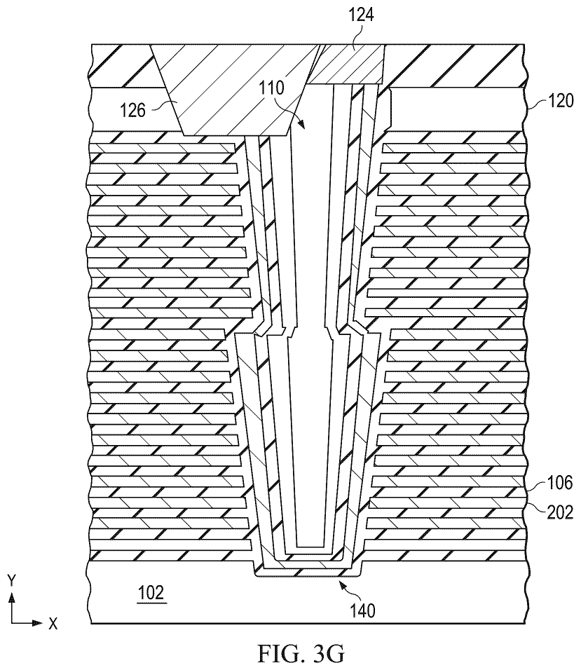

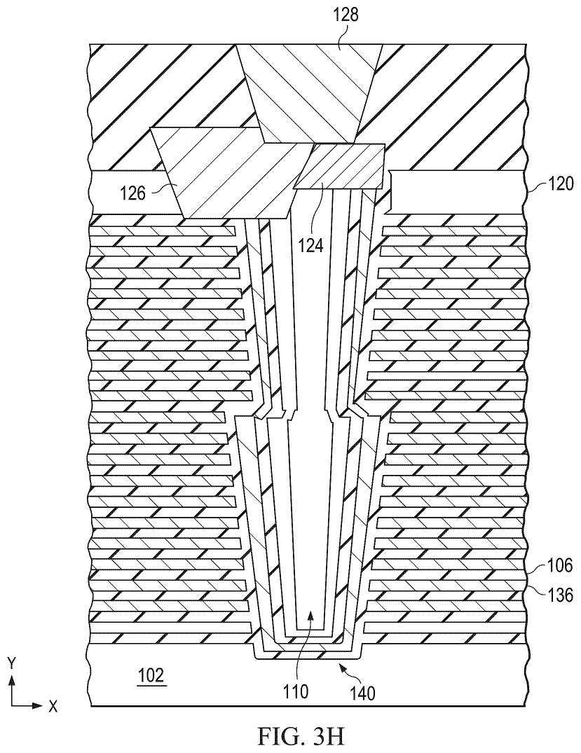

FIGS. 3A-3F illustrate cross-sectional view of an example semiconductor device with a channel plug at various stages of a fabrication process. As illustrated in FIG. 3A, an interleaved structure 204, select gate layers 120 and channel trenches 206 are formed. The formation process can be the same as or similar to the processing step as described in FIG. 2A. An interleaved structure 204 is formed which includes interleaved sacrificial layer 202 and insulating layer, e.g., first dielectric layer 106. The sacrificial layer 202 can be configured to be replaced with a conductive material to form gate lines 136 at a later stage of the process as described below in FIG. 3H. First dielectric layers 106 may comprise dielectric materials including, but not limited to, silicon oxide, silicon nitride, silicon oxynitride, or any combination thereof. Sacrificial layers 202 may include dielectric materials including, but not limited to, silicon oxide, silicon nitride, silicon oxynitride, or any combination thereof. Sacrificial layer 202 can comprise a different material than the first dielectric layer 106 such that it can be selectively removed at a later processing stage. For example, the sacrificial layer includes silicon nitride, while the first dielectric layer includes silicon oxide.

In some implementations, a select gate layer 120, e.g., for bottom select gate or source select gate, is formed on the substrate 102 prior to the formation of the interleaved structure 204. Another select gate layer 120 (e.g., for top select gate or drain select gate) is formed on top of the interleaved structure 204 along positive Y axis, as illustrated in FIG. 3A. The select gate layer 120 may comprise materials including but not limited to doped polysilicon. The first dielectric layers 106 and the sacrificial layers 202 can be deposited using one or more thin film deposition processes, including, but not limited to, chemical vapor deposition (CVD), physical vapor deposition (PVD), atomic layer deposition (ALD), sputtering, or any combination thereof. In some implementations, a second dielectric layer 222 can be formed on top of the select gate layer 120, as illustrated in FIG. 3A.

One or more channel trenches 206 are formed which extend through the select gate layer 120 and the interleaved structure 204 and in contact with the substrate 102. In some implementations, the channel trenches 206 extend partially into the substrate 102. In some implementations, the channel trench has a cylinder shape. Because of etching process, the cylinder may have a larger top opening compared to the bottom opening. In some implementations, the channel trench may be formed by stacking more than one cylinder trench, as shown in FIG. 3A. In such cases, a first portion 204(a) of interleaved structure 204 is deposited on the substrate 102 followed by a trench etch extending through the first portion of interleaved structure 204. The first portion of channel trenches 206 is then filled with a sacrificial filling material 208, which is configured to be removed at a later stage as described below. The sacrificial filling material 208 may include dielectric materials including, but not limited to, silicon oxide, silicon nitride, silicon oxynitride, or any combination thereof.

A second portion 204(b) of interleaved structure 204 and the select gate layer 120 is deposited on top of the first portion 204(a) of interleaved structure 204, followed by a trench etch process to form the second portion of channel trenches 206. As illustrated in FIG. 3A, the channel trenches 206 can have a stacked cylinder shape which extends through the second dielectric layer 222, the select gate layer 120, the interleaved structure 204, another select gate layer 120 and into the substrate 102. It is understood that between the interleaved structure 204 and the select gate layer 120, one or more additional dielectric layers can be deposited for isolation purpose. The trench etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

As illustrated in FIG. 3B, a layered structure 140 is formed on sidewalls of the channel trenches. The formation process can be same as or similar to the process described above in FIG. 2B. As noted above, the layered structure 140 comprises a blocking layer 122, a charge trapping layer 118 (also called storage layer in some cases), a dielectric layer 116 (also called a tunneling layer in some cases), and a semiconductor channel layer 114. The semiconductor channel layer 114, the dielectric layer 116, the charge trapping layer 118, and the blocking layer 122 are arranged radially from the center toward the outer surface of the channel trenches 206 in this order. This arrangement can be achieved by depositing theses layers sequentially on sidewalls of the channel trenches 206 in reverse order. Dielectric layer 116 may include silicon oxide, silicon oxynitride, or any combination thereof. Charge trapping layer 118 may include silicon nitride, silicon oxynitride, silicon, or any combination thereof. Blocking layer 122 may include silicon oxide, silicon oxynitride, high dielectric constant (high-k) dielectrics, or any combination thereof. Semiconductor channel layers 114 may include polysilicon. In one example, the layered structure 140 includes silicon oxide/silicon oxynitride (or silicon nitride)/silicon oxide/polysilicon (ONOP). The layered structure 140 can be deposited using one or more thin film deposition processes, including, but not limited to, chemical vapor deposition (CVD), physical vapor deposition (PVD), atomic layer deposition (ALD), sputtering, or any combination thereof. In some implementations, an implantation process is performed to dope the polysilicon for the semiconductor channel layer.

The layered structure 140 extends at least partially though the select gate layers 120 and the interleaved structure 204 along Y axis, as illustrated in FIG. 3B. The layered structure 140 can form a floating gate structure for the select gate layers 120, providing benefit of better threshold voltage Vt control for the top select gate and/or the bottom select gate.

A filling layer 112 is deposited into the vacancies of channel trenches 206. A channel structure 110 is formed which at least includes the layered structure 140 and the filling layer 112. The filling layer 112 can be a dielectric material, including but not limited to, silicon oxide, silicon nitride, silicon oxynitride, or any combination thereof.

As illustrated in FIG. 3C, a top portion of the filling layer 112 is recessed with an etching process. It is understood that the remaining filling layer 112 after recess may be higher or lower than a top surface 301 of the select gate layer 120 along Y axis. In some implementations, a top portion of the layered structure 140 is recessed (not shown) together with a top portion of the filling layer 112. The recess or etching process can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

As illustrated in FIG. 3D, the recessed space can be then filled with one or more materials to form a channel plug 124. In some implementations, the channel plug 124 can be made of materials including, but not limited to, TiN, TaN, Al, W, Cu, doped-polysilicon, silicides, or any combination thereof. In some implementations, the channel plug 124 can be first filled with an insulating material. More specifically, an insulating material can be first used to form the channel plug 124. The insulating material of the channel plug 124 is replaced with a conductive material in a later process stage. To replace the insulating materials with the conductive material, the insulating material can be partially or fully removed by dry etching or wet etching. The conductive material is then filled into the vacancies after etch.

In some implementations, as illustrated in FIGS. 3D-3E, the channel plug 124 fills the vacancies at the top portion of the channel structure 110 where both the filling layer 112 and the layered structure 140 are recessed. The remaining layered structure 140 after recess at least partially extends through the select gate layer 120. In other words, the top surface 305 of the remaining layered structure 140 is above the bottom surface 303 of the select gate layer 120 along Y axis (see FIG. 3D). This allows a floating gate configuration for select gates and provides a benefit of better threshold voltage Vt control. FIG. 3E diagram (a) illustrates the top view (e.g., X-Z plane) of a channel structure 110 before recess, while the diagram (b) illustrates the top view of the channel structure 110 after recess and formation of a channel plug 124.

In some implementations, a top portion of the channel structure 110 is not fully recessed along lateral directions (e.g., X axis and/or Z axis). As such, the width (e.g., a diameter) of channel plug 124 can be smaller than that of the channel structure 110 but larger than that of the semiconductor channel layer 114. As illustrated in FIG. 3F, diagram (a) shows the top view of a channel structure 110 before partial recess, while the diagram (b) shows the top view (e.g., X-Z plane) of a channel structure 110 after partial recess and formation of a channel plug 124. FIG. 3F diagram (b) illustrates that after partial recess the width (e.g., the diameter 307) of channel plug 124 is smaller than the diameter 311 of the channel structure 110 but larger than the diameter 309 of the semiconductor channel layer 114.

In some implementations, the cross-section of the channel structures 110 is circular, and the width (e.g., diameter 311 or diameter 307) of the channel plug 124 is larger than the width (e.g., diameter 309) of the semiconductor channel layer 114 that is in contact with the channel plug 124 (see FIGS. 3E-3F). In some implementations, the cross-section of the channel structures 110 is square, pentagonal, hexagonal or other shapes. The width in these cases can be a dimension in a plane (e.g., the X-Z plane in FIGS. 3E-3F) perpendicular to the axial axis (e.g., Y axis) of the channel structure 110. For example, the width is the length of a side of a square, pentagon, hexagon, or other shape. In another example, the width is the distance from the center to the outer edge of the channel structure 110.

In some implementations, after the channel plug 124 is deposited, a chemical mechanical polishing (CMP) process is on the surface of the channel plug 124 to align the top of the channel plug 124 with the upper surface of surrounding dielectric materials (see FIG. 3D).

As illustrated in FIG. 3G, a select gate cut structure 126 is formed. The formation process of the select gate cut structure 126 can be the same as or similar to the process as described in FIG. 2C. A select gate cut structure 126 is formed which extends through the select gate layer 120 along Y axis and partially into the channel structure 110 along X axis. The select gate cut structure 126 divides the select gate layer 120 into multiple isolated portions for electrically insulating select gate lines between two adjacent memory strings. As described below in FIG. 4, the select gate cut structure 126 is formed between two adjacent rows of channel structures 110 and is in contact with or extends into the channel structures 110 in these two adjacent rows. The select gate cut structure 126 may have a straight-line shape or a wavy shape extending along the Z axis on a top plane (e.g., the X-Z plane perpendicular to the Y axis), as shown in FIG. 4. In some implementations, the select gate cut structure 126 can be configured to avoid any contact or interference with the channel structures 110.

Referring back to FIG. 3G, the select gate cut structure 126 can be formed by etching trenches in combination with a lithography process in the select gate layer 120. A part of upper side of the channel structure 110 and the channel plug 124 can be removed during the trench etching process, exposing the semiconductor channel layer 114. The trenches are then filled with suitable materials (e.g., a dielectric material) to form the select gate cut structure 126. Thus, the select gate cut structure 126 partially extends into the channel structure 110 and the channel plug 124 and is in contact with the semiconductor channel layer 114.

In some implementations, the select gate cut structure 126 comprises a dielectric material. In some implementations, the select gate cut structure 126 comprises an insulating layer, an adhesive layer and a conductive layer. The insulating layer can comprise dielectric material, including but not limited to, silicon oxide, silicon nitride, silicon oxynitride, or any combination thereof. The adhesive layer can comprise material, including but not limited to, TiN, TaN, or any combination thereof. The conductive layer can comprise materials, including but not limited to, TiN, TaN, Al, W, Cu, doped-polysilicon, silicides, or any combination thereof. The insulating layer can be deposited by one or more thin film deposition processes including, but not limited to, CVD, PVD, ALD, MOCVD, MBE, sputtering, or any combination thereof. The conductive layer and the adhesive layer can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof.

As illustrated in FIG. 3H, a channel contact 128 is formed on top of both the select gate cut structure 126 and the channel plug 124. In some implementations, when the channel structures 110 are not interfered with the select gate cut structure 126 (see row 404 of channel structures 110 in FIG. 4A), the channel contact 128 is formed only on top of the channel plug 124. The channel contacts 128 can be isolated from one another with dielectric materials in between. The channel contact 128 can be configured to connect memory cells to bit lines (not shown), back end of line (BEOL) metal routings (not shown) and/or peripheral circuitry (not shown). The channel contact 128 can comprise conductive materials, including but not limited to, TiN, TaN, Al, W, Cu, doped-polysilicon, silicides, or any combination thereof.

The sacrificial layers 202 are replaced with a conductive material to form gate lines 136, as illustrated in FIG. 3H. The gate lines 136 are isolated from one another by the first dielectric layers 106. In some implementations, sacrificial layers 202 may be removed by a wet etch and/or dry etch process. After the removal of sacrificial layers 202, a plurality of openings may be formed between adjacent first dielectric layers 106. Then, a conductive material is deposited into the openings to form gate lines 136. In some implementations, gate lines 136 may include conductive materials including, but not limited to, W, Co, Cu, Al, polysilicon, doped silicon, silicides, or any combination thereof. In some implementations, the gate lines 136 may be formed by one or more thin film deposition processes including, but not limited to, CVD, PVD, ALD, MOCVD, MBE, sputtering, or any combination thereof.

FIGS. 4A-4B illustrate top plane views of a memory block or part of a memory block in a memory device 100. FIG. 4A illustrates multiple select gate cut structure 126 distributed in an array of channel structures 110. FIG. 4B illustrates a close view of relative position of the select gate cut structures 126 with respective to two adjacent channel structures 110.

In some implementations, a memory device 100 is a NAND Flash memory device in which memory cells are provided in the form of an array of NAND memory strings 406. A memory string 406 may include a plurality of channel structures 110, each extending vertically along Y axis above substrate 102 (see FIG. 1). A memory device 100 can include one or more memory blocks. A memory block may include a plurality of memory cells arranged between a pair of slit structures (not shown). The memory cells, arranged in an array, are formed in a plurality of channel structures 110 between slit structures. The memory device 100 may include one or more select gate cut structures 126, each between a pair of adjacent memory strings 406.

As illustrates in FIG. 4A diagram (a)-(b), the channel structures 110 are arranged in rows, each row extending along the Z direction. One or more rows of the channel structures 110 form a channel structure array 402. In some implementations, a channel structure array 402 with 12 channels, 16 channels, 20 channels, or even more channels can be formed. The select gate cut structure 126 can divide the select gate layer 120 and the channel structure array 402 into multiple portions.

In some implementations, select gate cut structure 126 may be a straight-line shape or a wavy shape structure in the top plan (e.g., the X-Z plane) of 3D memory device 100. In some implementations, the wavy shape of the select gate cut structure 126 has reduced interference with the channel structures 110 compared to the straight-line shape. Consequently, a greater amount of gate material from the select gate layer around the affected channel structures 110 remains intact with a wavy-shape configuration. The presence of more gate material enhances the select gate control. It is understood that, in some implementations, the select gate cut structure 126 has other suitable shapes (e.g., a zig-zag shape).

In some implementations, the select gate cut structure 126 is in contact with or partially extends into the channel structure 110 in adjacent two rows of channel structures 110. This configuration lowers the requirement for dummy rows of channel structures. Consequently, the density of channel structure 110 or memory cells is enhanced without dummy rows. This density improvement is especially beneficial in the context of highly-integrated circuits, where there is a desire for a three-dimensional memory that offers greater storage capacity within a compact assembly.

In some implementations, the select gate cut structure 126 is in contact with the semiconductor channel layer 114 of the channel structure 110 as illustrated in FIG. 4B diagram (b). In some implementations, the select gate cut structure 126 is not in contact with the semiconductor channel layer 114 of the channel structure 110 as illustrated in FIG. 4B diagram (a).

Although not shown, it is understood that, in some implementations, the select gate cut structure 126 can be configured to avoid any contact or interference with any channel structure 110 in two adjacent rows.

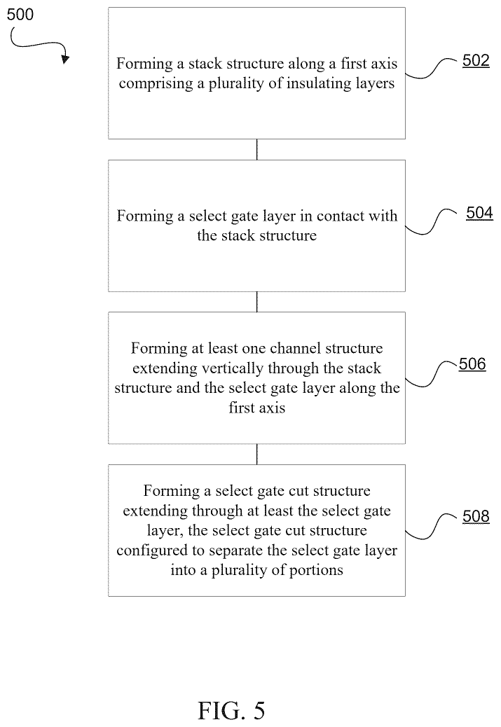

FIG. 5 illustrates a flow chart of an example process to form a semiconductor device. At step 502, a stack structure is formed along a first axis. The stack structure includes a plurality of insulating layers. The stack structure can be, e.g., the stack structure 104 of FIGS. 1, 2D and 3H, the interleaved structure 204 of FIGS. 2A-2C, 3A-3D, and 3G. The first axis can be, e.g., the Y axis of FIGS. 2A-2D,3A-3D and 3G-3H. The insulating layers can be, e.g., the first dielectric layer 106 of FIGS. 1-3D and 3G-3H.

At step 504, a select gate layer is formed. The select gate layer can be, e.g., the select gate layer 120 of FIGS. 1-3D and 3G-3H.

At step 506, at least one channel structure is formed which extends vertically through the stack structure and the select gate layer along the first axis. Each channel structure can include a layered structure. The layered structure comprises a blocking layer, a charge trapping layer, a dielectric layer, and a semiconductor channel layer. The channel structure can be, e.g., the channel structure 110 of FIGS. 1-3H. The layered structure can be, the layered structure 140 of FIGS. 1-3H. The blocking layer can be, e.g., the blocking layer 122 of FIGS. 1, 2B-2D and 3B-3H. The charge trapping layer can be, e.g., the charge trapping layer 118 of FIGS. 1, 2B-2D and 3B-3H. The dielectric layer can be, e.g., the dielectric layer 116 of FIGS. 1, 2B-2D and 3B-3H. The semiconductor channel layer can be, e.g., the semiconductor channel layer 114 of FIGS. 1, 2B-2D and 3B-3H.

In some implementations, each channel structure further includes a channel plug. The channel plug and the layered structure is stacked together along the first axis. The channel plug is in contact with the semiconductor channel layer. A width of the channel plug is larger than a width of the semiconductor channel layer. The channel plug can be, e.g., the channel plug 124 of FIGS. 1 and 3D-3H. The semiconductor channel layer can be, e.g., the semiconductor channel layer 114 of FIGS. 1, 2B-2D and 3B-3H.

At step 508, a select gate cut structure is formed which extends through at least the select gate layer. The select gate cut structure is configured to separate the select gate layer into a plurality of isolated portions. The select gate cut structure can be, e.g., the select gate cut structure 126 of FIGS. 1, 2C-2D and 3G-3H. The select gate layer can be, e.g., the select gate layer 120 of FIGS. 1-3D and 3G-3H.

In some implementations, the stack structure includes a plurality of sacrificial layers interleaved with the plurality of insulating layers, and the plurality of sacrificial layers are replaced with a plurality of conductive layers. The sacrificial layers can be, e.g., the sacrificial layer 202 of FIGS. 1-2C, 3A-3D, and 3G. The insulating layers can be, e.g., the first dielectric layer 106 of FIGS. 1-3D and 3G-3H. The conductive layers can be, e.g., the gate lines 136 of FIGS. 1, 2D and 3H.

In some implementations, a first material of the select gate layer is different from a second material of the at least one gate line. For example, the select gate layer includes a polysilicon, and the conductive layer (e.g., the gate lines 136) includes Tungsten (W).

In some implementations, the select gate cut structure is in contact with one or more channel structures of the at least one channel structure. The select gate cut structure can be, e.g., the select gate cut structure 126 of FIGS. 1, 2C-2D and 3G-3H. The channel structure can be, e.g., the channel structure 110 of FIGS. 1-3H.

In some implementations, the select gate cut structure has a straight-line shape or a wavy shape in a first plane of the semiconductor device, as illustrated in FIGS. 4A-4B, where the first plane (e.g., the X-Z plane) is orthogonal to the first axis (e.g., Y axis). The select gate cut structure can be, e.g., the select gate cut structure 126 of FIGS. 1, 2C-2D and 3G-3H.

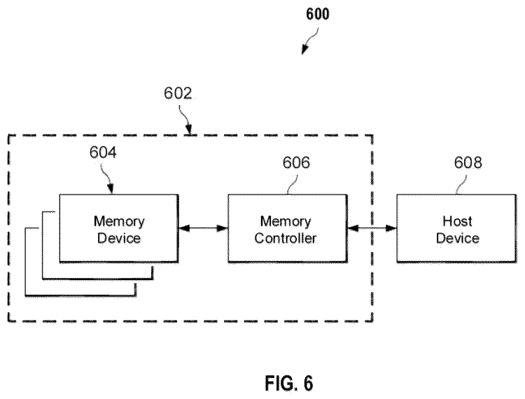

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the semiconductor device 100 of FIG. 1, or a part of the semiconductor device 100 of FIG. 1-4B, or a structure at an intermediate fabrication process of the semiconductor device 100 of FIG. 2A-3H.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures 110 via gate lines 136. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate 102, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a stack structure comprising at least one gate line, wherein the at least one gate line comprises a first material;
a select gate layer, wherein the select gate layer comprises a second material different from the first material; and
at least one channel structure extending through the stack structure and the select gate layer along a first axis, wherein each channel structure of the at least one channel structure comprises a layered structure.

2. The semiconductor device of claim 1, wherein the second material comprises a doped polysilicon.

3. The semiconductor device of claim 1, wherein the layered structure comprises a blocking layer, a charge trapping layer, a dielectric layer, and a semiconductor channel layer,
wherein the semiconductor channel layer is in contact with and laterally surrounded by the dielectric layer,
wherein the dielectric layer is in contact with and laterally surrounded by the charge trapping layer, and
wherein the charge trapping layer is in contact with and laterally surrounded by the blocking layer.

4. The semiconductor device of claim 3, wherein the blocking layer comprises silicon oxide, the charge trapping layer comprises silicon nitride, the dielectric layer comprises silicon oxide, and the semiconductor channel layer comprises doped polysilicon.

5. The semiconductor device of claim 1, further comprising a select gate cut structure extending through the select gate layer along the first axis and configured to separate the select gate layer into a plurality of isolated portions, wherein the select gate cut structure is in contact with one or more channel structures of the at least one channel structure.

6. The semiconductor device of claim 5, wherein the select gate cut structure has a straight-line shape or a wavy shape in a first plane of the semiconductor device, wherein the first plane is orthogonal to the first axis.

7. The semiconductor device of claim 3, wherein each channel structure of the at least one channel structure comprises a channel plug, and
wherein the channel plug and the layered structure is stacked together along the first axis, the channel plug is in contact with the semiconductor channel layer, and a width of the channel plug is larger than a width of the semiconductor channel layer.

8. The semiconductor device of claim 7, wherein the width of the channel plug is a dimension along a second axis, wherein the second axis is orthogonal to the first axis.

9. A semiconductor device, comprising:
a stack structure comprising at least one gate line;
a select gate layer;
at least one channel structure extending through at least the stack structure along a first axis, each channel structure of the at least one channel structure comprising:
a layered structure, the layered structure comprising a blocking layer, a charge trapping layer, a dielectric layer, and a semiconductor channel layer, and a channel plug, wherein the channel plug and the layered structure is stacked together along the first axis, wherein the channel plug is in contact with the semiconductor channel layer, and wherein the channel plug is at least partially in contact with a channel contact; and
a select gate cut structure extending through at least the select gate layer along the first axis and configured to separate the select gate layer into a plurality of isolated portions, wherein the select gate cut structure is in contact with one or more channel structures of the at least one channel structure.

10. The semiconductor device of claim 9, wherein a first material of the select gate layer is different from a second material of the at least one gate line.

11. The semiconductor device of claim 10, wherein the first material of the select gate layer comprises doped polysilicon, and the second material of the at least one gate line comprises tungsten.

12. The semiconductor device of claim 11, wherein the at least one channel structure extends through both the stack structure and the select gate layer along the first axis, and wherein the blocking layer comprises silicon oxide, the charge trapping layer comprises silicon nitride, the dielectric layer comprises silicon oxide, and the semiconductor channel layer comprises doped polysilicon.

13. The semiconductor device of claim 9, wherein a width of the channel plug is larger than a width of the semiconductor channel layer.

14. The semiconductor device of claim 9, wherein the select gate cut structure has a straight-line shape or a wavy shape in a first plane of the semiconductor device, wherein the first plane is orthogonal to the first axis.

15. A method for forming a semiconductor device, comprising:
forming a stack structure along a first axis comprising a plurality of insulating layers;
forming a select gate layer;
forming at least one channel structure extending through the stack structure and the select gate layer along the first axis, wherein each channel structure of the at least one channel structure comprises
a layered structure, the layered structure comprising a blocking layer, a charge trapping layer, a dielectric layer, and a semiconductor channel layer; and
forming a select gate cut structure extending through at least the select gate layer, the select gate cut structure configured to separate the select gate layer into a plurality of isolated portions.

16. The method for forming a semiconductor device of claim 15, wherein the stack structure further comprises a plurality of sacrificial layers interleaved with the plurality of insulating layers, and wherein the method further comprises replacing the plurality of sacrificial layers with a plurality of conductive layers.

17. The method for forming a semiconductor device of claim 16, wherein a first material of the select gate layer is different from a second material of the plurality of conductive layers.

18. The method for forming a semiconductor device of claim 15, wherein each channel structure of the at least one channel structure further comprises a channel plug,
wherein the channel plug and the layered structure is stacked together along the first axis,
wherein the channel plug is in contact with the semiconductor channel layer, and
wherein a width of the channel plug is larger than a width of the semiconductor channel layer.

19. The method for forming a semiconductor device of claim 15, wherein the select gate cut structure is in contact with one or more channel structures of the at least one channel structure.

20. The method for forming a semiconductor device of claim 15, wherein the select gate cut structure has a straight-line shape or a wavy shape in a first plane of the semiconductor device, wherein the first plane is orthogonal to the first axis.
